(19) United States
(12) Patent Application Publication
(10) Pub. No.: US 2017/0330843 A1
(43) Pub. Date: Nov. 16, 2017

(54) Advanced Moisture Resistant Structure of Compound Semiconductor Integrated Circuits

(71) Applicant: WIN Semiconductors Corp., Tao Yuan City (TW)

(72) Inventors: Chang Hwang Hua, Tao Yuan City (TW); Winson Shao, Tao Yuan City (TW)

(21) Appl. No.: 15/242,949

(22) Filed: Aug. 22, 2016

(30) Foreign Application Priority Data
May 13, 2016 (TW) 105114950

(51) Int. Cl. H01L 23/00; H01L 29/06; H01L 27/06

(52) U.S. Cl. CPC H01L 23/564; H01L 27/0629; H01L 29/0649

(57) ABSTRACT

An advanced moisture resistant structure of compound semiconductor integrated circuit comprises a compound semiconductor substrate, a compound semiconductor epitaxial structure, a compound semiconductor integrated circuit and a moisture barrier layer. The compound semiconductor epitaxial structure is formed on the compound semiconductor substrate. The compound semiconductor integrated circuit is foimed on the compound semiconductor epitaxial structure. The moisture barrier layer is formed on the compound semiconductor integrated circuit. The moisture barrier layer is made of A1₂O₃. The thickness of the moisture barrier layer is greater than or equal to 400 Å and less than or equal to 1000 Å so as to enhance the moisture resistant ability of the compound semiconductor integrated circuit.

### FIELD OF THE INVENTION

The present invention relates to an advanced moisture resistant structure of compound semiconductor integrated circuit, especially an advanced moisture resistant structure of compound semiconductor integrated circuit containing an aluminum oxide layer.

### BACKGROUND OF THE INVENTION

Please refer to FIG. 4A, which is a cross-sectional schematic view of a heterojunction bipolar transistor of an embodiment of compound semiconductor integrated circuit of conventional technology. A first compound semiconductor epitaxial structure 5 is formed on a compound semiconductor substrate 4. A second compound semiconductor epitaxial structure 50 is formed on the first compound semiconductor epitaxial structure 5. Two collector electrodes 22 are formed respectively on the first compound semiconductor epitaxial structure 5 beside the two sides of the second compound semiconductor epitaxial structure 50. A third compound semiconductor epitaxial structure 51 is formed on the second compound semiconductor epitaxial structure 50, wherein the third compound semiconductor epitaxial structure 51 is divided into two regions. Three base electrodes 20 are formed respectively on the second compound semiconductor epitaxial structure 50, and the three base electrodes 20 and the two regions of the third compound semiconductor epitaxial structure 51 are formed alternatively on the second compound semiconductor epitaxial structure 50. Two emitter electrodes 21 are formed respectively on the two regions of the third compound semiconductor epitaxial structure 51. A conventional technology moisture barrier layer 62 is formed on the heterojunction bipolar transistor and the first compound semiconductor epitaxial structure 5. The conventional technology moisture barrier layer 62 is made of SiNₓ. Usually the thickness of the conventional technology moisture barrier layer 62 is 5000 Å. The conventional technology moisture barrier layer 62 covers a top surface of the first compound semiconductor epitaxial structure 5, and also covers an outer surface of the heterojunction bipolar transistor, wherein the outer surface of the heterojunction bipolar transistor includes the outer surfaces of the structures of the second compound semiconductor epitaxial structure 50, the third compound semiconductor epitaxial structure 51, the three base electrodes 20, the two emitter electrodes 21 and the two collector electrodes 22. However, after the biased highly accelerated temperature and humidity stress test (bHAST), the failure rate of the heterojunction bipolar transistor covered by the conventional technology moisture barrier layer 62 is significantly too high. That is the moisture resistant ability of the conventional technology moisture barrier layer 62 is insufficient.

Furthermore, when forming the compound semiconductor integrated circuit on the compound semiconductor substrate or the first compound semiconductor epitaxial structure 5, defects, such as some irregular shapes of defects such as protrusion, depression or slit etc., would occur in some local areas. These irregular shapes of defects like protrusion, depression or slit etc. do not really affect the electrical characteristics and the efficiency of the compound semiconductor integrated circuit. However, due to these irregular shapes of defects like protrusion, depression or slit etc., sometimes the covering would not be effectively and fully when the conventional technology moisture barrier layer 62 is placed to cover the compound semiconductor integrated circuit. Or some part of the covering might be so thin and weak that the moisture resistant ability of the compound semiconductor integrated circuit is reduced, and thereby the failure rate of the compound semiconductor integrated circuit is significantly increased.

Accordingly, the present invention has developed a new design which may avoid the above mentioned drawbacks, may significantly enhance the performance of the devices and may take into account economic considerations. Therefore, the present invention then has been invented.

### SUMMARY OF THE INVENTION

There are two main technical problems that the present invention is seeking to solve. The first one is how to provide an excellent design and material for the moisture barrier layer so as to efficiently enhance the moisture resistant ability of the compound semiconductor integrated circuit. The second is how to provide an excellent design and material for the moisture barrier layer so as to solve the problem that it is not able to effectively fully cover the moisture barrier layer on the compound semiconductor integrated circuit due to these irregular shapes of defects like protrusion, depression or slit etc., and the problem that some part of the covering might be so thin and weak that the moisture resistant ability of the compound semiconductor integrated circuit is reduced, and thereby the failure rate of the compound semiconductor integrated circuit is significantly increased.

In order to solve the problems mentioned the above and to achieve the expected effect, the present invention provides an advanced moisture resistant structure of compound semiconductor integrated circuit comprising a compound semiconductor substrate, a compound semiconductor epitaxial structure, a compound semiconductor integrated circuit and a moisture barrier layer. The compound semiconductor epitaxial structure is formed on the compound semiconductor substrate. The compound semiconductor integrated circuit is formed on the compound semiconductor epitaxial structure. The moisture barrier layer is formed on the compound semiconductor integrated circuit. The moisture barrier layer is made of Al₂O₃. A thickness of the moisture barrier layer is greater than or equal to 400 Å and less than or equal to 1000 Å so as to enhance the moisture resistant ability of the compound semiconductor integrated circuit.

In an embodiment, the compound semiconductor integrated circuit includes at least one of an active component and a passive component.

In an embodiment, the active component includes at least one selected from the group consisting of a heterojunction bipolar transistor (HBT), a high electron mobility transistor (HEMT), a pseudomorphic high electron mobility transistor (pHEMT), a gallium nitride high electron mobility transistor (GaN HEMT), a bipolar junction transistor (BJT) and a field effect transistor (FET).

In an embodiment, the compound semiconductor integrated circuit includes at least one electrical wire.

In an embodiment, the compound semiconductor substrate is made of one material selected from the group consisting of quartz, GaAs, sapphire, InP, GaP, SiC, diamond and GaN.

In an embodiment, the moisture barrier layer covers an external surface of the compound semiconductor integrated circuit.

Furthermore, the present invention further provides an advanced moisture resistant structure of compound semiconductor integrated circuit comprising a compound semiconductor substrate, a compound semiconductor epitaxial structure, a compound semiconductor integrated circuit and a moisture barrier layer. The compound semiconductor epitaxial structure is formed on the compound semiconductor substrate. The compound semiconductor integrated circuit is formed on the compound semiconductor epitaxial structure. The moisture barrier layer is formed on the compound semiconductor integrated circuit. The moisture barrier layer includes a first moisture barrier layer and a second moisture barrier layer, wherein the first moisture barrier layer is made of Al₂O₃, a thickness of the first moisture barrier layer is greater than or equal to 100 Å and less than or equal to 1000 Å, wherein the second moisture barrier layer is made of one material selected from the group consisting of silicon nitride (SiNₓ), Polybenzoxazole (PBO), Benzocyclobutene (BCB) and Polyimide, so as to enhance the moisture resistant ability of the compound semiconductor integrated circuit.

In an embodiment, the second moisture barrier layer is formed on the compound semiconductor integrated circuit, the first moisture barrier layer is formed on the second moisture barrier layer.

In an embodiment, the second moisture barrier layer is made of one material selected from the group consisting of Polybenzoxazole, Benzocyclobutene and Polyimide, and a thickness of the second moisture barrier layer is greater than or equal to 1 μm and less than or equal to 10 μm.

In an embodiment, the second moisture barrier layer is made of silicon nitride, and a thickness of the second moisture barrier layer is greater than or equal to 1000 Å and less than or equal to 10000 Å.

In an embodiment, the first moisture barrier layer is formed on the compound semiconductor integrated circuit, the second moisture barrier layer is Ruined on the first moisture barrier layer.

In an embodiment, the second moisture barrier layer is made of silicon nitride, and a thickness of the second moisture barrier layer is greater than or equal to 1000 Å and less than or equal to 10000 Å.

In an embodiment, the compound semiconductor integrated circuit includes at least one of an active component and a passive component.

In an embodiment, the active component includes at least one selected from the group consisting of a heterojunction bipolar transistor, a high electron mobility transistor, a pseudomorphic high electron mobility transistor, a gallium nitride high electron mobility transistor, a bipolar junction transistor and a field effect transistor.

In an embodiment, the compound semiconductor integrated circuit includes at least one electrical wire.

In an embodiment, the compound semiconductor substrate is made of one material selected from the group consisting of quartz, GaAs, sapphire, InP, GaP, SiC, diamond and GaN.

In an embodiment, the moisture barrier layer covers an external surface of the compound semiconductor integrated circuit.

In an embodiment, the second moisture barrier layer is made of one material selected from the group consisting of Polybenzoxazole, Benzocyclobutene and Polyimide, and a thickness of the second moisture barrier layer is greater than or equal to 1 μm and less than or equal to 10 μm.

For further understanding the characteristics and effects of the present invention, some preferred embodiments referred to drawings are in detail described as follows.

### BRIEF DESCRIPTION OF DRAWINGS

FIG. 1A is a schematic top view of an embodiment of an advanced moisture resistant structure of compound semiconductor integrated circuit of the present invention.

FIG. 1B is a partial enlargement schematic top view of a heterojunction bipolar transistor of the block a region in FIG. 1A.

FIG. 1C is a cross-sectional schematic view of a heterojunction bipolar transistor of along the section line b-b′ in FIG. 1B.

FIG. 1D is a cross-sectional schematic view of a pseudomorphic high electron mobility transistor of another embodiment of an advanced moisture resistant structure of compound semiconductor integrated circuit of the present invention.

FIG. 1E is a partial enlargement cross-sectional SEM image of an embodiment of an advanced moisture resistant structure of compound semiconductor integrated circuit of the present invention.

FIG. 2A is a cross-sectional schematic view of a heterojunction bipolar transistor of another embodiment of an advanced moisture resistant structure of compound semiconductor integrated circuit of the present invention.

FIG. 2B is a cross-sectional schematic view of a pseudomorphic high electron mobility transistor of another embodiment of an advanced moisture resistant structure of compound semiconductor integrated circuit of the present invention.

FIG. 2C is a partial enlargement cross-sectional SEM image of a source electrode of a pseudomorphic high electron mobility transistor of the block d region in FIG. 2B.

FIG. 2D is a partial enlargement cross-sectional SEM image of a gate electrode of a pseudomorphic high electron mobility transistor of the block e region in FIG. 2B.

FIG. 2E is a partial enlargement cross-sectional SEM image of a drain electrode of a pseudomorphic high electron mobility transistor of the block f region in FIG. 2B.

FIG. 2F is a partial enlargement cross-sectional SEM image of another embodiment of an advanced moisture resistant structure of compound semiconductor integrated circuit of the present invention.

FIG. 3A is a cross-sectional schematic view of a heterojunction bipolar transistor of another embodiment of an advanced moisture resistant structure of compound semiconductor integrated circuit of the present invention.

FIG. 3B is a cross-sectional schematic view of a pseudomorphic high electron mobility transistor of another embodiment of an advanced moisture resistant structure of compound semiconductor integrated circuit of the present invention.

FIG. 4A is a cross-sectional schematic view of a heterojunction bipolar transistor of an embodiment of compound semiconductor integrated circuit of conventional technology.

### DETAILED DESCRIPTIONS OF PREFERRED EMBODIMENTS

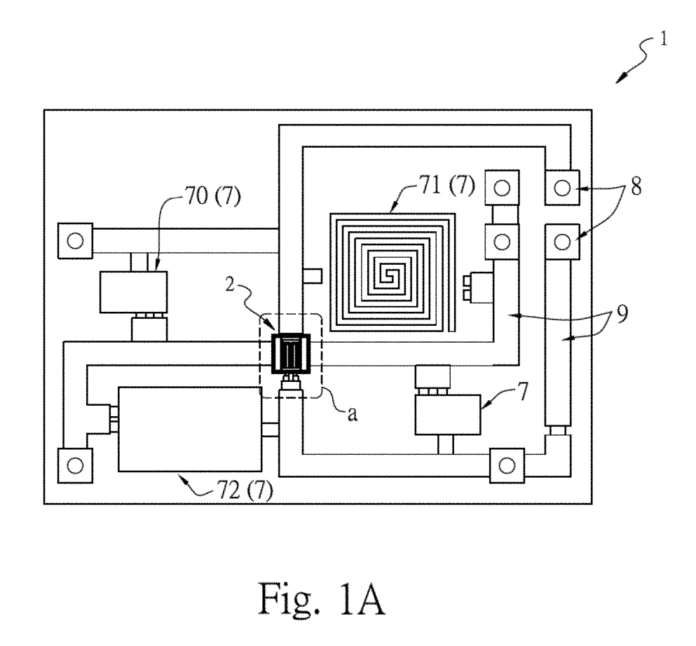

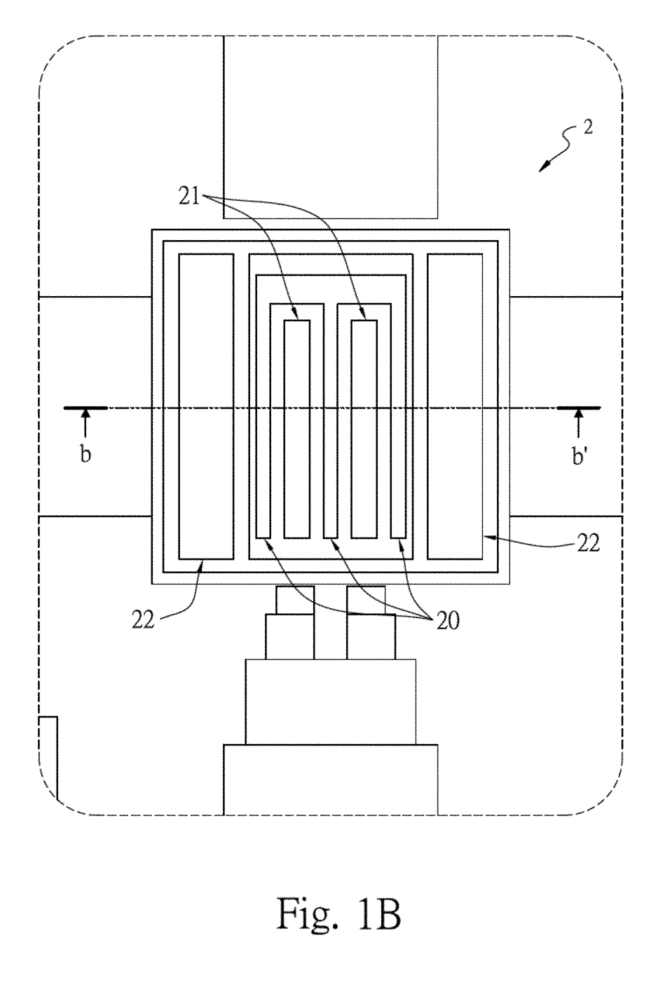

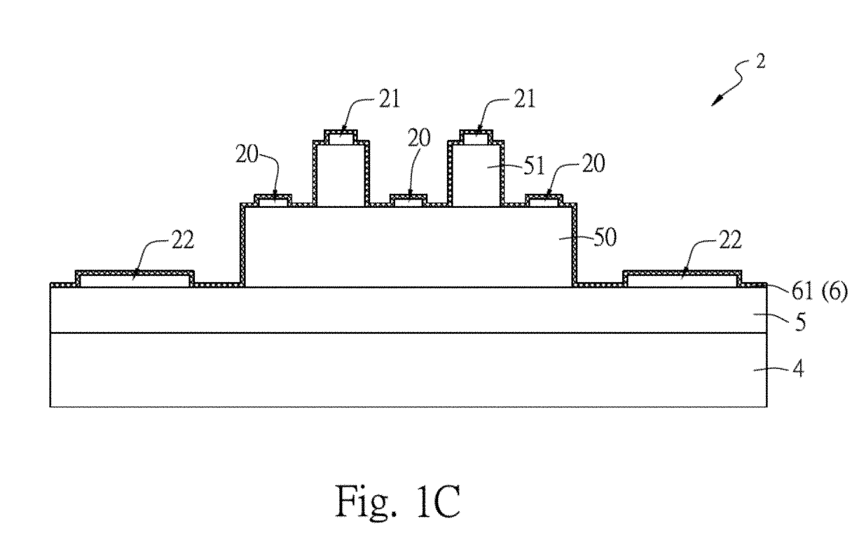

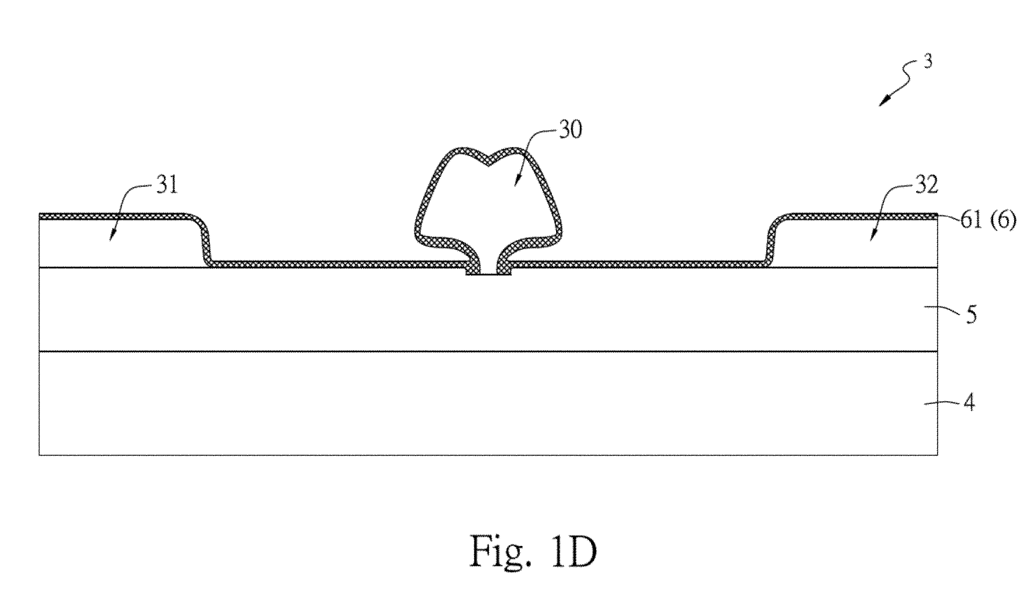

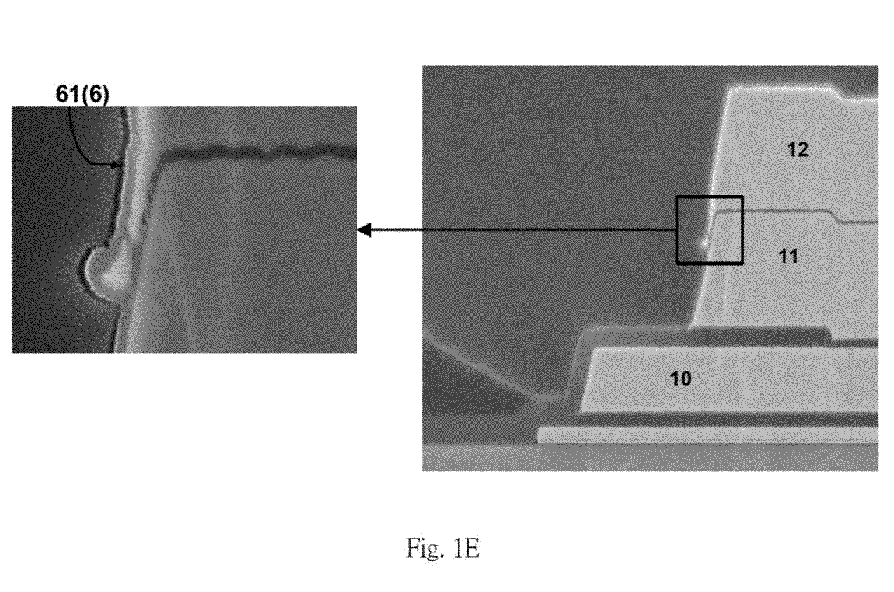

Please refer to FIG. 1A, which is a schematic top view of an embodiment of an advanced moisture resistant structure of compound semiconductor integrated circuit of the present invention. In the embodiment, the compound semiconductor integrated circuit 1 comprises a heterojunction bipolar transistor 2, a plural of passive components 7, a plural of pads 8, and a plural of electrical wires 9. The passive components 7 include a resistor 70, a inductor 71 and a capacitor 72. Please also refer to FIG. 1B, which is a partial enlargement schematic top view of a heterojunction bipolar transistor of the block a region in FIG. 1A. The heterojunction bipolar transistor 2 includes three base electrodes 20, two emitter electrodes 21 and two collector electrodes 22. Please also refer to FIG. 1C, which is a cross-sectional schematic view of a heterojunction bipolar transistor of along the section line b-b′ in FIG. 1B. A first compound semiconductor epitaxial structure 5 is formed on a compound semiconductor substrate 4. A second compound semiconductor epitaxial structure 50 is formed on the first compound semiconductor epitaxial structure 5. Two collector electrodes 22 are formed respectively on the first compound semiconductor epitaxial structure 5 beside the two sides of the second compound semiconductor epitaxial structure 50. A third compound semiconductor epitaxial structure 51 is formed on the second compound semiconductor epitaxial structure 50, wherein the third compound semiconductor epitaxial structure 51 is divided into two regions. Three base electrodes 20 are formed respectively on the second compound semiconductor epitaxial structure 50, and the three base electrodes 20 and the two regions of the third compound semiconductor epitaxial structure 51 are formed alternatively on the second compound semiconductor epitaxial structure 50. Two emitter electrodes 21 are formed respectively on the two regions of the third compound semiconductor epitaxial structure 51. A moisture barrier layer 6 is formed on the compound semiconductor integrated circuit 1, the first compound semiconductor epitaxial structure 5 and the compound semiconductor substrate 4. The moisture barrier layer 6 is composed of an aluminum oxide (Al₂O₃) layer 61. A thickness of the aluminum oxide layer 61 (the moisture barrier layer 6) is greater than or equal to 400 Å and less than or equal to 1000 Å. The aluminum oxide layer 61 (the moisture barrier layer 6) is deposited on the compound semiconductor integrated circuit 1, the first compound semiconductor epitaxial structure 5 and the compound semiconductor substrate 4 by atomic layer chemical vapor deposition system (ALD). Although the reference sign of the aluminum oxide layer 61 (the moisture barrier layer 6) is not shown in FIG. 1A, in fact the aluminum oxide layer 61 (the moisture barrier layer 6) fully covers a top surface of the first compound semiconductor epitaxial structure 5 (not shown in Figure) and an exposed outer surface of the compound semiconductor integrated circuit 1, including the outer surfaces of the heterojunction bipolar transistor 2, the plural of passive components 7 (including the resistor 70, the inductor 71 and the capacitor 72), and the plural of electrical wires 9. FIG. 1C shows that the aluminum oxide layer 61 (the moisture barrier layer 6) covers the top surface of the first compound semiconductor epitaxial structure 5, and also covers the outer surface of the heterojunction bipolar transistor 2, wherein the outer surface of the heterojunction bipolar transistor 2 includes the outer surfaces of the second compound semiconductor epitaxial structure 50, the third compound semiconductor epitaxial structure 51, the three base electrodes 20, the two emitter electrodes 21 and the two collector electrodes 22. Therefore, the aluminum oxide layer 61 (the moisture barrier layer 6) fully covers the outer surface of the heterojunction bipolar transistor 2 and the top surface of the first compound semiconductor epitaxial structure 5 such that the heterojunction bipolar transistor 2 and the first compound semiconductor epitaxial structure 5 are not exposed to the air, thereby the moisture resistant ability of the compound semiconductor integrated circuit 1 is enhanced. The compound semiconductor substrate 4 is made of one material selected from the group consisting of quartz, GaAs, sapphire, InP, GaP, SiC, diamond and GaN.

In the embodiments of the present invention, when the moisture barrier layer 6 is composed of a single aluminum oxide layer 61, a thickness of the moisture barrier layer 6 (the aluminum oxide layer 61) is within the range of greater than or equal to 400 Å and less than or equal to 1000 Å, greater than or equal to 420 Å and less than or equal to 1000 Å, greater than or equal to 450 Å and less than or equal to 1000 Å, greater than or equal to 470 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In an embodiment, the first compound semiconductor epitaxial structure 5 may include a buffer layer (not shown in Figure) and a subcollector layer (not shown in Figure); the second compound semiconductor epitaxial structure 50 may include a collector layer (not shown in Figure) and a base layer (not shown in Figure); the third compound semiconductor epitaxial structure 51 may include an emitter layer (not shown in Figure), an emitter cap layer (not shown in Figure) and an emitter contact layer (not shown in Figure). In another embodiment, the first compound semiconductor epitaxial structure 5 may include a subcollector layer (not shown in Figure). In an embodiment, the third compound semiconductor epitaxial structure 51 may include an emitter layer (not shown in Figure) and an emitter contact layer (not shown in Figure). In another embodiment, the third compound semiconductor epitaxial structure 51 may include an emitter layer (not shown in Figure) and an emitter cap layer (not shown in Figure). In an embodiment, the third compound semiconductor epitaxial structure 51 may include an emitter layer (not shown in Figure). In an embodiment, the aluminum oxide layer 61 (the moisture barrier layer 6) may fully cover an outer surface of a cap of a filter (not shown in Figure), wherein the filter may be a film bulk acoustic resonator, a bulk acoustic wave filter or a surface acoustic wave filter. In an embodiment, the active component may also be an optical device, such as a vertical cavity surface emitting laser, a laser printing head or a laser diode.

Please refer to FIG. 1D, which is a cross-sectional schematic view of a pseudomorphic high electron mobility transistor of another embodiment of an advanced moisture resistant structure of compound semiconductor integrated circuit of the present invention. A first compound semiconductor epitaxial structure 5 is formed on a compound semiconductor substrate 4. In the embodiment, a compound semiconductor integrated circuit 1 comprises a pseudomorphic high electron mobility transistor 3. The pseudomorphic high electron mobility transistor 3 includes a gate electrode 30, a source electrode 31 and a drain electrode 32, wherein the gate electrode 30 is formed on the first compound semiconductor epitaxial structure 5, the source electrode 31 and the drain electrode 32 are formed respectively at two sides of the gate electrode 30 on the first compound semiconductor epitaxial structure 5. A moisture barrier layer 6 is formed on the compound semiconductor integrated circuit 1, the first compound semiconductor epitaxial structure 5 and the compound semiconductor substrate 4. The moisture barrier layer 6 is composed of an aluminum oxide (Al₂O₃) layer 61. A thickness of the aluminum oxide layer 61 (the moisture barrier layer 6) is greater than or equal to 400 Å and less than or equal to 1000 Å. The aluminum oxide layer 61 (the moisture barrier layer 6) is deposited on the compound semiconductor integrated circuit 1, the first compound semiconductor epitaxial structure 5 and the compound semiconductor substrate 4 by atomic layer chemical vapor deposition system (ALD). FIG. 1D shows that the aluminum oxide layer 61 (the moisture barrier layer 6) covers a top surface of the first compound semiconductor epitaxial structure 5, and also covers an outer surface of the pseudomorphic high electron mobility transistor 3. The outer surface of the pseudomorphic high electron mobility transistor 3 includes the outer surfaces of the gate electrode 30, the source electrode 31 and the drain electrode 32. Therefore, the aluminum oxide layer 61 (the moisture barrier layer 6) fully covers the outer surface of the pseudomorphic high electron mobility transistor 3 and the top surface of the first compound semiconductor epitaxial structure 5 such that the pseudomorphic high electron mobility transistor 3 and the first compound semiconductor epitaxial structure 5 are not exposed to the air, thereby the moisture resistant ability of the compound semiconductor integrated circuit 1 is enhanced. The compound semiconductor substrate 4 is made of one material selected from the group consisting of quartz, GaAs, sapphire, InP, GaP, SiC, diamond and GaN.

In the embodiments of the present invention, when the moisture barrier layer 6 is composed of a single aluminum oxide layer 61, a thickness of the moisture barrier layer 6 (the aluminum oxide layer 61) is within the range of greater than or equal to 400 Å and less than or equal to 1000 Å, greater than or equal to 420 Å and less than or equal to 1000 Å, greater than or equal to 450 Å and less than or equal to 1000 Å, greater than or equal to 470 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In an embodiment, the first compound semiconductor epitaxial structure 5 may include a buffer layer (not shown in Figure), a channel layer (not shown in Figure), a spacer layer (not shown in Figure) and a Schottky barrier layer (not shown in Figure). In another embodiment, the first compound semiconductor epitaxial structure 5 may include a buffer layer (not shown in Figure), a barrier layer (not shown in Figure), a channel layer (not shown in Figure), a spacer layer (not shown in Figure) and a Schottky barrier layer (not shown in Figure).

Please refer to FIG. 1E, which is a partial enlargement cross-sectional SEM image of an embodiment of an advanced moisture resistant structure of compound semiconductor integrated circuit of the present invention. In the embodiment, as shown in the right hand side of FIG. 1E, it comprises a first metal layer 10, a second metal layer 11 and a third metal layer 12. An aluminum oxide layer 61 (the moisture bather layer 6) covers an outer surface of the third metal layer 12 and an outer surface of the second metal layer 11. The left hand side of Figure lE shows the partial enlargement of the black block in the right hand side of FIG. 1E. The third metal layer 12 is formed on the second metal layer 11. Part of the protrusion of the third metal layer 12 covers the sidewall near the top of the second metal layer 11. The figure shows the aluminum oxide layer 61 (the moisture barrier layer 6) deposited by atomic layer chemical vapor deposition system (ALD) fully covers the outer surface of the third metal 12 and the outer surface of the second metal layer 11 (including the protrusion of the third metal layer 12 covered on the sidewall near the top of the second metal layer 11).

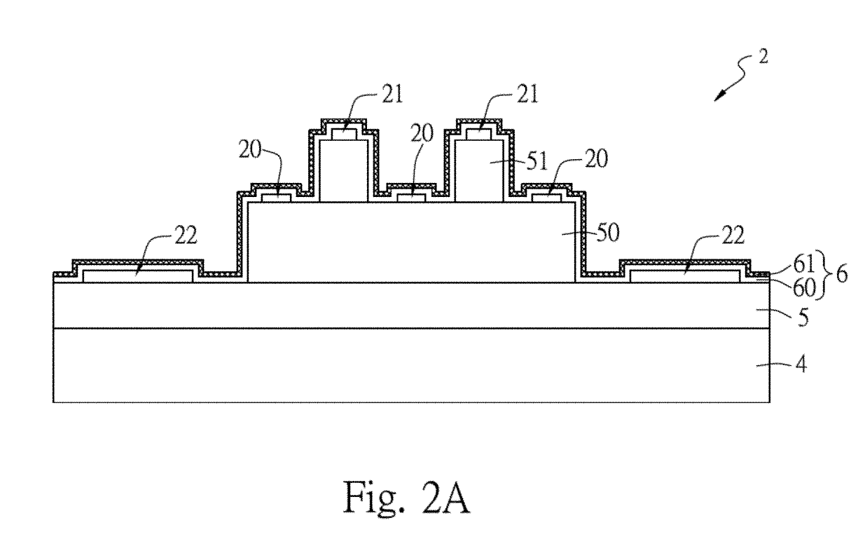

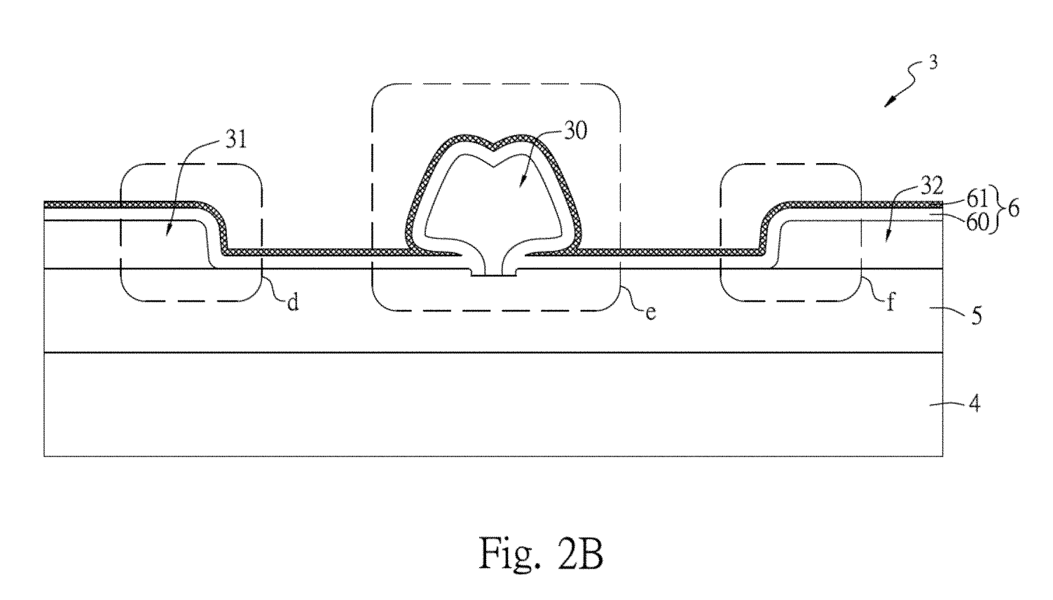

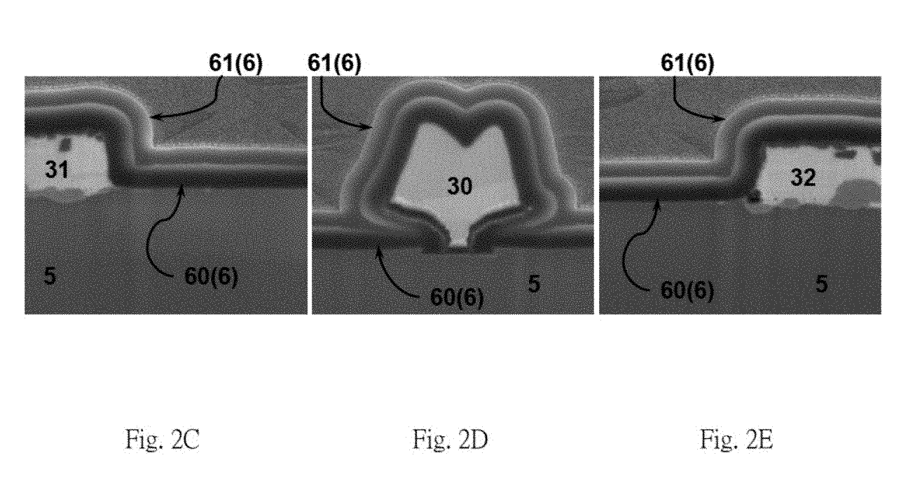

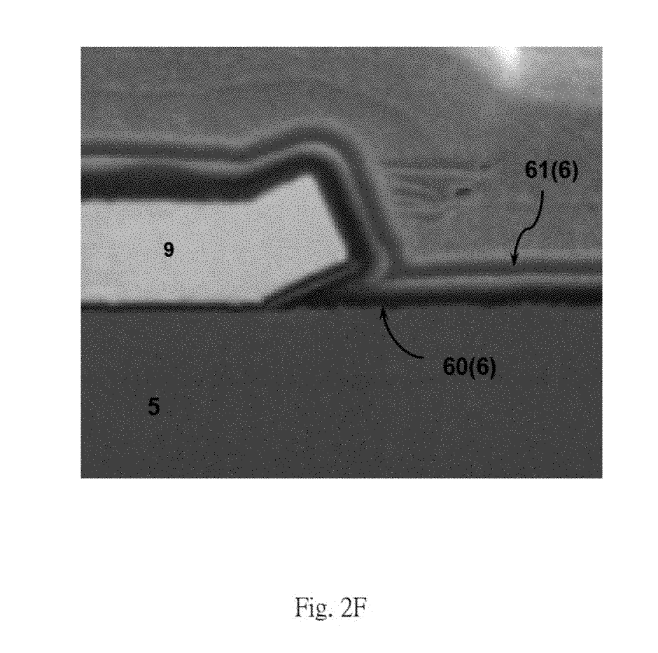

Please refer to FIG. 2A, which is a cross-sectional schematic view of a heterojunction bipolar transistor of another embodiment of an advanced moisture resistant structure of compound semiconductor integrated circuit of the present invention. The main structure of the heterojunction bipolar transistor 2 of the embodiment is mostly similar to the structure of the heterojunction bipolar transistor 2 of the embodiment shown in FIG. 1C, except that the moisture barrier layer 6 comprises a first moisture barrier layer 61 and a second moisture barrier layer 60, wherein the second moisture barrier layer 60 is firstly formed on the compound semiconductor integrated circuit 1, the first compound semiconductor epitaxial structure 5 and the compound semiconductor substrate 4; and then the first moisture barrier layer 61 is formed on the second moisture barrier layer 60 such that the moisture barrier layer 6 (including the first moisture barrier layer 61 and the second moisture barrier layer 60) is formed on the compound semiconductor integrated circuit 1, the first compound semiconductor epitaxial structure 5 and the compound semiconductor substrate 4. The second moisture barrier layer 60 is made of one material selected from the group consisting of silicon nitride (SiNₓ), Polybenzoxazole (PBO), Benzocyclobutene (BCB) and Polyimide. When the second moisture barrier layer 60 is made of silicon nitride (SiNₓ), a thickness of the second moisture barrier layer 60 is greater than or equal to 1000 Å and less than or equal to 10000 Å; while the second moisture barrier layer 60 is made of one material selected from the group consisting of Polybenzoxazole (PBO), Benzocyclobutene (BCB) and Polyimide, the thickness of the second moisture barrier layer 60 is greater than or equal to 1 μm and less than or equal to 10 μm. The first moisture barrier layer 61 is made of aluminum oxide (Al₂O₃). A thickness of the first moisture barrier layer 61 (aluminum oxide layer) is greater than or equal to 100 Å and less than or equal to 1000 Å. The first moisture barrier layer 61 (aluminum oxide layer) is deposited on the second moisture barrier layer 60 by atomic layer chemical vapor deposition system (ALD). FIG. 2A shows that the moisture barrier layer 6 (including the first moisture barrier layer 61 which is the aluminum oxide layer and the second moisture barrier layer 60) covers a top surface of the first compound semiconductor epitaxial structure 5, and also covers an outer surface of the heterojunction bipolar transistor 2. The outer surface of the heterojunction bipolar transistor 2 includes the outer surfaces of the second compound semiconductor epitaxial structure 50, the third compound semiconductor epitaxial structure 51, the three base electrodes 20, the two emitter electrodes 21 and the two collector electrodes 22. Therefore, the moisture barrier layer 6 (including the first moisture barrier layer 61 which is the aluminum oxide layer and the second moisture barrier layer 60) fully covers the outer surface of the heterojunction bipolar transistor 2 and the top surface of the first compound semiconductor epitaxial structure 5 such that the heterojunction bipolar transistor 2 and the first compound semiconductor epitaxial structure 5 are not exposed to the air, thereby the moisture resistant ability of the compound semiconductor integrated circuit 1 is enhanced.

In the embodiments of the present invention, when the moisture barrier layer 6 is composed of a first moisture barrier layer 61 and a second moisture barrier layer 60, a thickness of the first moisture barrier layer 61 (aluminum oxide layer) is within the range of greater than or equal to 100 Å and less than or equal to 1000 Å, greater than or equal to 120 Å and less than or equal to 1000 Å, greater than or equal to 150 Å and less than or equal to 1000 Å, greater than or equal to 170 Å and less than or equal to 1000 Å, greater than or equal to 200 Å and less than or equal to 1000 Å, greater than or equal to 250 Å and less than or equal to 1000 Å, greater than or equal to 300 Å and less than or equal to 1000 Å, greater than or equal to 350 Å and less than or equal to 1000 Å, greater than or equal to 400 Å and less than or equal to 1000 Å, greater than or equal to 450 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In the embodiments of the present invention, when the second moisture barrier layer 60 is made of silicon nitride (SiNₓ), a thickness of the second moisture barrier layer 60 is within the range of greater than or equal to 1200 Å and less than or equal to 10000 Å, greater than or equal to 1500 Å and less than or equal to 10000 Å, greater than or equal to 1700 Å and less than or equal to 10000 Å, greater than or equal to 2000 Å and less than or equal to 10000 Å, greater than or equal to 2200 Å and less than or equal to 10000 Å, greater than or equal to 2500 Å and less than or equal to 10000 Å, greater than or equal to 2700 Å and less than or equal to 10000 Å, greater than or equal to 3000 Å and less than or equal to 10000 Å, greater than or equal to 3300 Å and less than or equal to 10000 Å, greater than or equal to 3500 Å and less than or equal to 10000 Å, greater than or equal to 3700 Å and less than or equal to 10000 Å, greater than or equal to 4000 Å and less than or equal to 10000 Å, greater than or equal to 4500 Å and less than or equal to 10000 Å, or greater than or equal to 5000 Å and less than or equal to 10000 Å.

In the embodiments of the present invention, when the second moisture barrier layer 60 is made of one material selected from the group consisting of Polybenzoxazole (PBO), Benzocyclobutene (BCB) and Polyimide, the thickness of the second moisture barrier layer 60 is within the range of greater than or equal to 1 μm and less than or equal to 10 μm, greater than or equal to 1.2 μm and less than or equal to 10 μm, greater than or equal to 1.5 μm and less than or equal to 10 μm, greater than or equal to 1.7 μm and less than or equal to 10 μm, greater than or equal to 2 μm and less than or equal to 10 μm, greater than or equal to 2.5 μm and less than or equal to 10 μm, greater than or equal to 3 μm and less than or equal to 10 μm, greater than or equal to 3.5 μm and less than or equal to 10 μm, or greater than or equal to 4 μm and less than or equal to 10 μm.

Please refer to FIG. 2B, which is a cross-sectional schematic view of a pseudomorphic high electron mobility transistor of another embodiment of an advanced moisture resistant structure of compound semiconductor integrated circuit of the present invention. The main structure of the pseudomorphic high electron mobility transistor 3 of the embodiment is mostly similar to the structure of the pseudomorphic high electron mobility transistor 3 of the embodiment shown in FIG. 1D, except that the moisture barrier layer 6 comprises a first moisture barrier layer 61 and a second moisture barrier layer 60, wherein the second moisture barrier layer 60 is firstly formed on the compound semiconductor integrated circuit 1, the first compound semiconductor epitaxial structure 5 and the compound semiconductor substrate 4; and then the first moisture barrier layer 61 is formed on the second moisture barrier layer 60 such that the moisture barrier layer 6 (including the first moisture barrier layer 61 and the second moisture barrier layer 60) is formed on the compound semiconductor integrated circuit 1, the first compound semiconductor epitaxial structure 5 and the compound semiconductor substrate 4. The second moisture barrier layer 60 is made of one material selected from the group consisting of silicon nitride (SiNₓ), Polybenzoxazole (PBO), Benzocyclobutene (BCB) and Polyimide. When the second moisture barrier layer 60 is made of silicon nitride (SiNₓ), a thickness of the second moisture barrier layer 60 is greater than or equal to 1000 Å and less than or equal to 10000 Å; while the second moisture barrier layer 60 is made of one material selected from the group consisting of Polybenzoxazole (PBO), Benzocyclobutene (BCB) and Polyimide, the thickness of the second moisture barrier layer 60 is greater than or equal to 1 μm and less than or equal to 10 μm. The first moisture barrier layer 61 is made of aluminum oxide (Al₂O₃). A thickness of the first moisture barrier layer 61 (aluminum oxide layer) is greater than or equal to 100 Å and less than or equal to 1000 Å. The first moisture barrier layer 61 (aluminum oxide layer) is deposited on the second moisture barrier layer 60 by atomic layer chemical vapor deposition system (ALD). FIG. 2B shows that the moisture barrier layer 6 (including the first moisture barrier layer 61 which is the aluminum oxide layer and the second moisture barrier layer 60) covers a top surface of the first compound semiconductor epitaxial structure 5, and also covers an outer surface of the pseudomorphic high electron mobility transistor 3. The outer surface of the pseudomorphic high electron mobility transistor 3 includes the outer surfaces of the gate electrode 30, the source electrode 31 and the drain electrode 32. Therefore, the moisture barrier layer 6 (including the first moisture barrier layer 61 which is the aluminum oxide layer and the second moisture barrier layer 60) fully covers the outer surface of the pseudomorphic high electron mobility transistor 3 and the top surface of the first compound semiconductor epitaxial structure 5 such that the pseudomorphic high electron mobility transistor 3 and the first compound semiconductor epitaxial structure 5 are not exposed to the air, thereby the moisture resistant ability of the compound semiconductor integrated circuit 1 is enhanced.

In the embodiments of the present invention, when the moisture barrier layer 6 is composed of a first moisture barrier layer 61 and a second moisture barrier layer 60, a thickness of the first moisture barrier layer 61 (aluminum oxide layer) is within the range of greater than or equal to 100 Å and less than or equal to 1000 Å, greater than or equal to 120 Å and less than or equal to 1000 Å, greater than or equal to 150 Å and less than or equal to 1000 Å, greater than or equal to 170 Å and less than or equal to 1000 Å, greater than or equal to 200 Å and less than or equal to 1000 Å, greater than or equal to 250 Å and less than or equal to 1000 Å, greater than or equal to 300 Å and less than or equal to 1000 Å, greater than or equal to 350 Å and less than or equal to 1000 Å, greater than or equal to 400 Å and less than or equal to 1000 Å, greater than or equal to 450 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In the embodiments of the present invention, when the second moisture barrier layer 60 is made of silicon nitride (SiNₓ), a thickness of the second moisture barrier layer 60 is within the range of greater than or equal to 1200 Å and less than or equal to 10000 Å, greater than or equal to 1500 Å and less than or equal to 10000 Å, greater than or equal to 1700 Å and less than or equal to 10000 Å, greater than or equal to 2000 Å and less than or equal to 10000 Å, greater than or equal to 2200 Å and less than or equal to 10000 Å, greater than or equal to 2500 Å and less than or equal to 10000 Å, greater than or equal to 2700 Å and less than or equal to 10000 Å, greater than or equal to 3000 Å and less than or equal to 10000 Å, greater than or equal to 2300 Å and less than or equal to 10000 Å, greater than or equal to 3500 Å and less than or equal to 10000 Å, greater than or equal to 3700 Å and less than or equal to 10000 Å, greater than or equal to 4000 Å and less than or equal to 10000 Å, greater than or equal to 4500 Å and less than or equal to 10000 Å, or greater than or equal to 5000 Å and less than or equal to 10000 Å.

In the embodiments of the present invention, when the second moisture barrier layer 60 is made of one material selected from the group consisting of Polybenzoxazole (PBO), Benzocyclobutene (BCB) and Polyimide, the thickness of the second moisture barrier layer 60 is within the range of greater than or equal to 1 μm and less than or equal to 10 μm, greater than or equal to 1.2 μm and less than or equal to 10 μm, greater than or equal to 1.5 μm and less than or equal to 10 μm, greater than or equal to 1.7 μm and less than or equal to 10 μm, greater than or equal to 2 μm and less than or equal to 10 μm, greater than or equal to 2.5 μm and less than or equal to 10 μm, greater than or equal to 3 μm and less than or equal to 10 μm, greater than or equal to 3.5 μm and less than or equal to 10 μm, or greater than or equal to 4 μm and less than or equal to 10 μm.

Please refer to FIG. 2C, 2D and 2E, which are respectively the partial enlargement cross-sectional SEM images of a source electrode (the block d region), a gate electrode (the block e region) and a drain electrode (the block f region) of a pseudomorphic high electron mobility transistor in FIG. 2B. FIG. 2C, 2D and 2E show that the second moisture barrier layer 60 covers the top surface of the first compound semiconductor epitaxial structure 5 and the outer surface of the pseudomorphic high electron mobility transistor 3 including the outer surfaces of the gate electrode 30, the source electrode 31 and the drain electrode 32. In FIG. 2D, the structure of the bottom of the gate electrode 30 is the gate shrink structure. However when forming the moisture barrier layer 6 on the gate electrode 30, the gap of the moisture barrier layer 6 covering would most easily occur around the bottom of the gate electrode 30 (the gate shrink structure). Therefore, using the moisture barrier layer 6 having the first moisture barrier layer 61 which is the aluminum oxide layer and the second moisture barrier layer 60 may more fully cover the bottom of the gate electrode 30 (the gate shrink structure), thereby enhances the moisture resistant ability of the compound semiconductor integrated circuit 1.

Please refer to FIG. 2F, which is a partial enlargement cross-sectional SEM image of another embodiment of an advanced moisture resistant structure of compound semiconductor integrated circuit of the present invention. An electrical wire 9 is formed on a first compound semiconductor epitaxial structure 5. A moisture barrier layer 6 (including a first moisture barrier layer 61 which is an aluminum oxide layer and a second moisture barrier layer 60) covers the electrical wire 9 and the first compound semiconductor epitaxial structure 5. The electrical wire 9 tilts up at the right hand side of the interface with the first compound semiconductor epitaxial structure 5 such that a slit is generated between the tilt up of the electrical wire 9 and the first compound semiconductor epitaxial structure 5. Hence, when forming the moisture barrier layer 6, the gap of the moisture barrier layer 6 covering would most easily occur around the slit. Therefore, using the moisture barrier layer 6 having the first moisture barrier layer 61 which is the aluminum oxide layer and the second moisture barrier layer 60 may more fully cover the slit, thereby enhances the moisture resistant ability of the compound semiconductor integrated circuit 1.

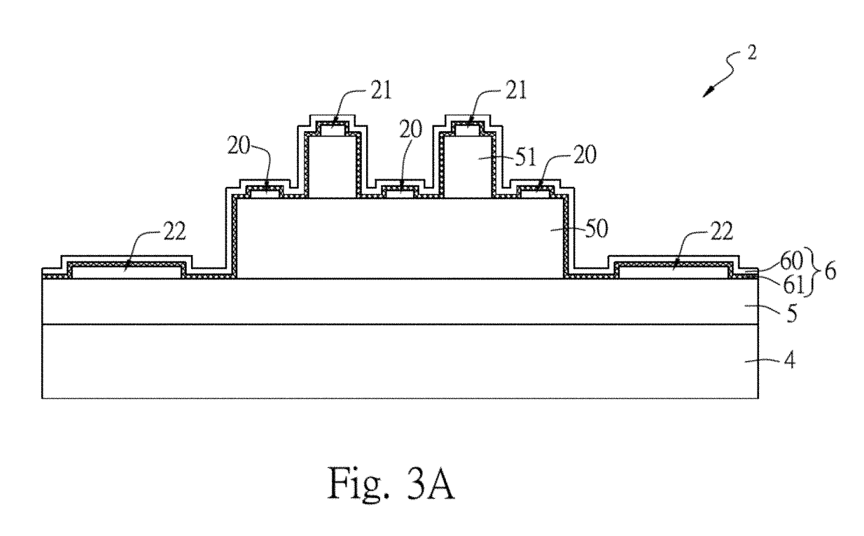

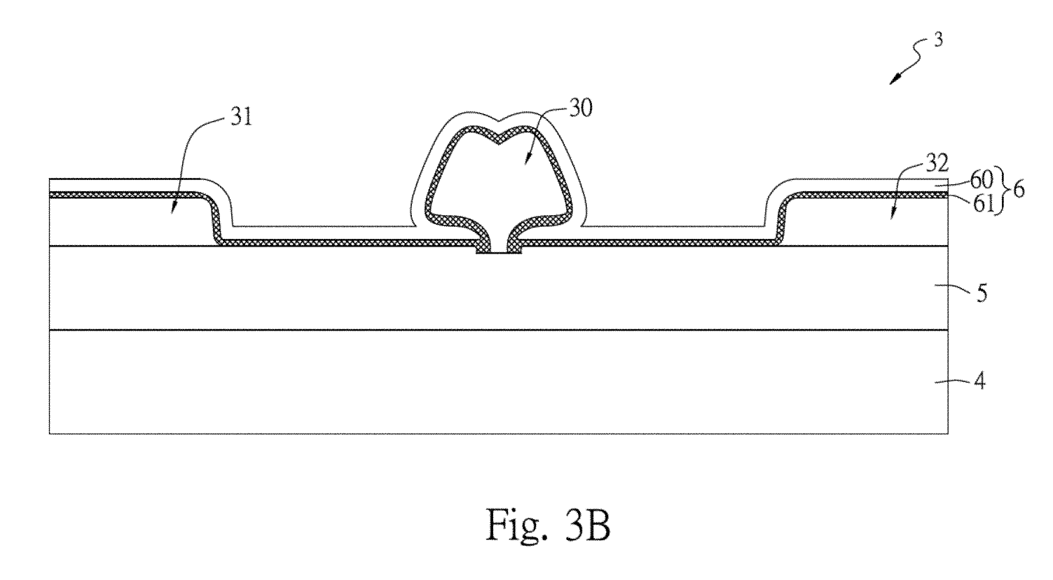

In the embodiments of the present invention of FIGS. 2A and 2B, the first moisture barrier layer 61 (aluminum oxide layer) of the moisture barrier layer 6 is formed on the second moisture barrier layer 60 of the moisture barrier layer 6; while in the embodiments of the present invention of FIGS. 3A and 3B, the second moisture barrier layer 60 of the moisture barrier layer 6 is formed on the first moisture barrier layer 61 (aluminum oxide layer) of the moisture barrier layer 6.

Please refer to FIG. 3A, which is a cross-sectional schematic view of a heterojunction bipolar transistor of another embodiment of an advanced moisture resistant structure of compound semiconductor integrated circuit of the present invention. The main structure of the heterojunction bipolar transistor 2 of the embodiment is mostly similar to the structure of the heterojunction bipolar transistor 2 of the embodiment shown in FIG. 1C, except that the moisture barrier layer 6 comprises a first moisture barrier layer 61 and a second moisture barrier layer 60, wherein the first moisture barrier layer 61 is firstly fonned on the compound semiconductor integrated circuit 1, the first compound semiconductor epitaxial structure 5 and the compound semiconductor substrate 4; and then the second moisture barrier layer 60 is formed on the first moisture barrier layer 61 such that the moisture barrier layer 6 (including the first moisture barrier layer 61 and the second moisture barrier layer 60) is formed on the compound semiconductor integrated circuit 1, the first compound semiconductor epitaxial structure 5 and the compound semiconductor substrate 4. The first moisture barrier layer 61 is made of aluminum oxide (Al₂O₃). A thickness of the first moisture barrier layer 61 (aluminum oxide layer) is greater than or equal to 100 Å and less than or equal to 1000 Å. The first moisture barrier layer 61 (aluminum oxide layer) is deposited on the compound semiconductor integrated circuit 1, the first compound semiconductor epitaxial structure 5 and the compound semiconductor substrate 4 by atomic layer chemical vapor deposition system (ALD). The second moisture barrier layer 60 is made of silicon nitride (SiNₓ). A thickness of the second moisture barrier layer 60 is greater than or equal to 1000 Å and less than or equal to 10000 Å. FIG. 3A shows that the moisture barrier layer 6 (including the first moisture barrier layer 61 which is the aluminum oxide layer and the second moisture barrier layer 60) covers a top surface of the first compound semiconductor epitaxial structure 5, and also covers an outer surface of the heterojunction bipolar transistor 2. The outer surface of the heterojunction bipolar transistor 2 includes the outer surfaces of the second compound semiconductor epitaxial structure 50, the third compound semiconductor epitaxial structure 51, the three base electrodes 20, the two emitter electrodes 21 and the two collector electrodes 22. Therefore, the moisture barrier layer 6 (including the first moisture barrier layer 61 which is the aluminum oxide layer and the second moisture barrier layer 60) fully covers the outer surface of the heterojunction bipolar transistor 2 and the top surface of the first compound semiconductor epitaxial structure 5 such that the heterojunction bipolar transistor 2 and the first compound semiconductor epitaxial structure 5 are not exposed to the air, thereby the moisture resistant ability of the compound semiconductor integrated circuit 1 is enhanced.

In the embodiments of the present invention, when the moisture barrier layer 6 is composed of a first moisture barrier layer 61 and a second moisture barrier layer 60, a thickness of the first moisture barrier layer 61 (aluminum oxide layer) is within the range of greater than or equal to 100 Å and less than or equal to 1000 Å, greater than or equal to 120 Å and less than or equal to 1000 Å, greater than or equal to 150 Å and less than or equal to 1000 Å, greater than or equal to 170 Å and less than or equal to 1000 Å, greater than or equal to 200 Å and less than or equal to 1000 Å, greater than or equal to 250 Å and less than or equal to 1000 Å, greater than or equal to 300 Å and less than or equal to 1000 Å, greater than or equal to 350 Å and less than or equal to 1000 Å, greater than or equal to 400 Å and less than or equal to 1000 Å, greater than or equal to 450 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In the embodiments of the present invention, when the second moisture barrier layer 60 is made of silicon nitride (SiNₓ), a thickness of the second moisture barrier layer 60 is within the range of greater than or equal to 1200 Å and less than or equal to 10000 Å, greater than or equal to 1500 Å and less than or equal to 10000 Å, greater than or equal to 1700 Å and less than or equal to 10000 Å, greater than or equal to 2000 Å and less than or equal to 10000 Å, greater than or equal to 2200 Å and less than or equal to 10000 Å, greater than or equal to 2500 Å and less than or equal to 10000 Å, greater than or equal to 2700 Å and less than or equal to 10000 Å, greater than or equal to 3000 Å and less than or equal to 10000 Å, greater than or equal to 3300 Å and less than or equal to 10000 Å, greater than or equal to 3500 Å and less than or equal to 10000 Å, greater than or equal to 3700 Å and less than or equal to 10000 Å, greater than or equal to 4000 Å and less than or equal to 10000 Å, greater than or equal to 4500 Å and less than or equal to 10000 Å, or greater than or equal to 5000 Å and less than or equal to 10000 Å.

In the embodiments of the present invention, when the second moisture barrier layer 60 is made of one material selected from the group consisting of Polybenzoxazole (PBO), Benzocyclobutene (BCB) and Polyimide, the thickness of the second moisture barrier layer 60 is within the range of greater than or equal to 1 μm and less than or equal to 10 μm, greater than or equal to 1.2 μm and less than or equal to 10 μm, greater than or equal to 1.5 μm and less than or equal to 10 μm, greater than or equal to 1.7 μm and less than or equal to 10 μm, greater than or equal to 2 μm and less than or equal to 10 μm, greater than or equal to 2.5 μm and less than or equal to 10 μm, greater than or equal to 3 μm and less than or equal to 10 μm, greater than or equal to 3.5 μm and less than or equal to 10 μm, or greater than or equal to 4 μm and less than or equal to 10 μm.

Please refer to FIG. 3B, which is a cross-sectional schematic view of a pseudomorphic high electron mobility transistor of another embodiment of an advanced moisture resistant structure of compound semiconductor integrated circuit of the present invention. The main structure of the pseudomorphic high electron mobility transistor 3 of the embodiment is mostly similar to the structure of the pseudomorphic high electron mobility transistor 3 of the embodiment shown in FIG. 1D, except that the moisture barrier layer 6 comprises a first moisture barrier layer 61 and a second moisture barrier layer 60, wherein the first moisture barrier layer 61 is firstly formed on the compound semiconductor integrated circuit 1, the first compound semiconductor epitaxial structure 5 and the compound semiconductor substrate 4; and then the second moisture barrier layer 60 is formed on the first moisture barrier layer 61 such that the moisture barrier layer 6 (including the first moisture barrier layer 61 and the second moisture barrier layer 60) is formed on the compound semiconductor integrated circuit 1, the first compound semiconductor epitaxial structure 5 and the compound semiconductor substrate 4. The first moisture barrier layer 61 is made of aluminum oxide (Al₂O₃). A thickness of the first moisture barrier layer 61 (aluminum oxide layer) is greater than or equal to 100 Å and less than or equal to 1000 Å. The first moisture barrier layer 61 (aluminum oxide layer) is deposited on the compound semiconductor integrated circuit 1, the first compound semiconductor epitaxial structure 5 and the compound semiconductor substrate 4 by atomic layer chemical vapor deposition system (ALD). The second moisture barrier layer 60 is made of silicon nitride (SiNₓ). A thickness of the second moisture barrier layer 60 is greater than or equal to 1000 Å and less than or equal to 10000 Å. FIG. 3B shows that the moisture barrier layer 6 (including the first moisture barrier layer 61 which is the aluminum oxide layer and the second moisture barrier layer 60) covers a top surface of the first compound semiconductor epitaxial structure 5, and also covers an outer surface of the pseudomorphic high electron mobility transistor 3. The outer surface of the pseudomorphic high electron mobility transistor 3 includes the outer surfaces of the gate electrode 30, the source electrode 31 and the drain electrode 32. Therefore, the moisture barrier layer 6 (including the first moisture barrier layer 61 which is the aluminum oxide layer and the second moisture barrier layer 60) fully covers the outer surface of the pseudomorphic high electron mobility transistor 3 and the top surface of the first compound semiconductor epitaxial structure 5 such that the pseudomorphic high electron mobility transistor 3 and the first compound semiconductor epitaxial structure 5 are not exposed to the air, thereby the moisture resistant ability of the compound semiconductor integrated circuit 1 is enhanced.

In the embodiments of the present invention, when the moisture barrier layer 6 is composed of a first moisture barrier layer 61 and a second moisture barrier layer 60, a thickness of the first moisture barrier layer 61 (aluminum oxide layer) is within the range of greater than or equal to 100 Å and less than or equal to 1000 Å, greater than or equal to 120 Å and less than or equal to 1000 Å, greater than or equal to 150 Å and less than or equal to 1000 Å, greater than or equal to 170 Å and less than or equal to 1000 Å, greater than or equal to 200 Å and less than or equal to 1000 Å, greater than or equal to 250 Å and less than or equal to 1000 Å, greater than or equal to 300 Å and less than or equal to 1000 Å, greater than or equal to 350 Å and less than or equal to 1000 Å, greater than or equal to 400 Å and less than or equal to 1000 Å, greater than or equal to 450 Å and less than or equal to 1000 Å, greater than or equal to 500 Å and less than or equal to 1000 Å, greater than or equal to 550 Å and less than or equal to 1000 Å, greater than or equal to 600 Å and less than or equal to 1000 Å, greater than or equal to 650 Å and less than or equal to 1000 Å, or greater than or equal to 700 Å and less than or equal to 1000 Å.

In the embodiments of the present invention, when the second moisture barrier layer 60 is made of silicon nitride (SiNₓ), a thickness of the second moisture barrier layer 60 is within the range of greater than or equal to 1200 Å and less than or equal to 10000 Å, greater than or equal to 1500 Å and less than or equal to 10000 Å, greater than or equal to 1700 Å and less than or equal to 10000 Å, greater than or equal to 2000 Å and less than or equal to 10000 Å, greater than or equal to 2200 Å and less than or equal to 10000 Å, greater than or equal to 2500 Å and less than or equal to 10000 Å, greater than or equal to 2700 Å and less than or equal to 10000 Å, greater than or equal to 3000 Å and less than or equal to 10000 Å, greater than or equal to 3300 Å and less than or equal to 10000 Å, greater than or equal to 3500 Å and less than or equal to 10000 Å, greater than or equal to 3700 Å and less than or equal to 10000 Å, greater than or equal to 4000 Å and less than or equal to 10000 Å, greater than or equal to 4500 Å and less than or equal to 10000 Å, or greater than or equal to 5000 Å and less than or equal to 10000 Å.

In the embodiments of the present invention, when the second moisture barrier layer 60 is made of one material selected from the group consisting of Polybenzoxazole (PBO), Benzocyclobutene (BCB) and Polyimide, the thickness of the second moisture barrier layer 60 is within the range of greater than or equal to and less than or equal to 10 μm, greater than or equal to 1.2 μm and less than or equal to 10 μm, greater than or equal to 1.5 μm and less than or equal to 10 μm, greater than or equal to 1.7 μm and less than or equal to 10 μm, greater than or equal to 2 μm and less than or equal to 10 μm, greater than or equal to 2.5 μm and less than or equal to 10 μm, greater than or equal to 3 μm and less than or equal to 10 μm, greater than or equal to 3.5 μm and less than or equal to 10 μm, or greater than or equal to 4 μm and less than or equal to 10 μm.

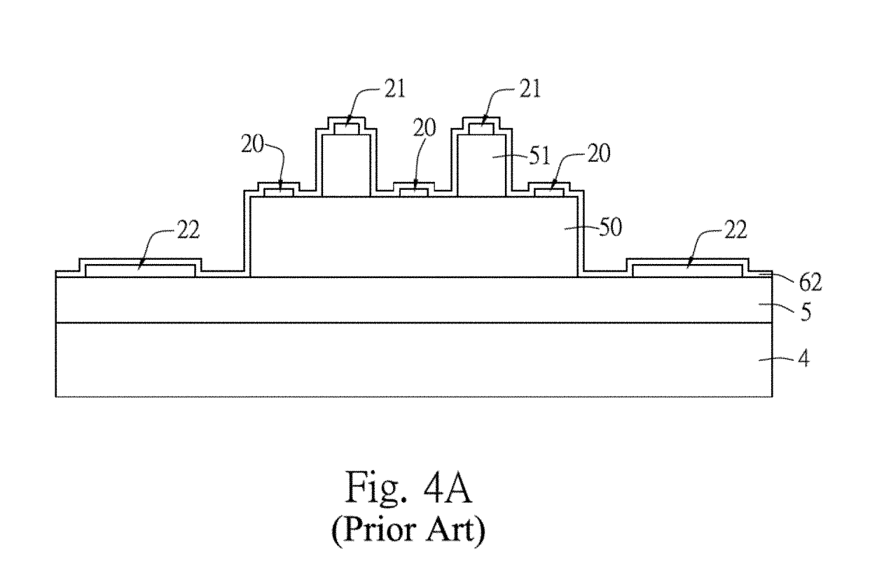

Applicant uses different types of the moisture barrier layer to cover the heterojunction bipolar transistor 2 and then put the heterojunction bipolar transistors 2 covered with different types of the moisture barrier layer into the biased highly accelerated temperature and humidity stress test. The different types and thickness of the moisture barrier layer are as following: 1. the embodiment of conventional technology of FIG. 4A, SiNₓ 5000 Å; 2. the embodiment of the present invention of FIG. 1C, Al₂O₃ 400 Å; 3. the embodiment of the present invention of FIG. 1C, Al₂O₃ 500 Å; 4. the embodiment of the present invention of FIG. 2A, Al₂O₃ 200 Å/SiNₓ 5000 Å; and 5. the embodiment of the present invention of FIG. 3A, SiNₓ 5000 Å/Al₂O₃ 200 Å. After the biased highly accelerated temperature and humidity stress test, the test result shows as Table 1.

TABLE 1

| | bHAST |
|---|---|
| Type of the moisture barrier layer | failure rate |
| SiNₓ 5000 Å | 6/80 = 7.5% |
| (the embodiment of conventional technology of FIG. 4A) | |
| Al₂O₃ 400 Å | 0/80 = 0% |
| (the embodiment of the present invention of FIG. 1C) | |
| Al₂O₃ 500 Å | 0/80 = 0% |
| (the embodiment of the present invention of FIG. 1C) | |
| Al₂O₃ 200 Å/SiNₓ 5000 Å | 0/80 = 0% |
| (the embodiment of the present invention of FIG. 2A) | |
| SiNₓ 5000 Å/Al₂O₃ 200 Å | 1/80 = 1.25% |
| (the embodiment of the present invention of FIG. 3A) | |

From the test result of Table 1, it is very clear that, no matter the moisture barrier layer 6 of the present invention is composed of a single aluminum oxide layer 61 or composed of a first moisture barrier layer 61 and a second moisture barrier layer 60, after the biased highly accelerated temperature and humidity stress test, the failure rate of the heterojunction bipolar transistor 2 covered by the moisture barrier layer 6 of the present invention is much lower than that of the heterojunction bipolar transistor covered by conventional technology moisture barrier layer SiNₓ 5000 Å.

No matter the moisture barrier layer 6 of the present invention is composed of a single aluminum oxide layer 61 or composed of a first moisture barrier layer 61 and a second moisture barrier layer 60, the moisture barrier layer 6 may fully covers the compound semiconductor integrated circuit 1, the first compound semiconductor epitaxial structure 5 and the compound semiconductor substrate 4. Therefore, the compound semiconductor integrated circuit 1 is prevented from contacting with the outside air. Hence, the moisture barrier layer 6 of the present invention has the function for protecting the compound semiconductor integrated circuit 1 such that the compound semiconductor integrated circuit 1 may not be oxidized easily. And the moisture barrier layer 6 of the present invention also has the function for protecting the outer surface of the compound semiconductor integrated circuit 1 such that the scratch resistance of the compound semiconductor integrated circuit 1 is enhanced.

No matter the moisture barrier layer 6 of the present invention is composed of a single aluminum oxide layer 61 or composed of a first moisture barrier layer 61 and a second moisture barrier layer 60, when the moisture barrier layer 6 covers on the active component or the passive component, the moisture resistant ability may be enhanced. The active component is not limited to be the heterojunction bipolar transistor 2 or the pseudomorphic high electron mobility transistor 3. The active component may also be an optical device, such as a vertical cavity surface emitting laser, a laser printing head or a laser diode. The active component may also be a field effect transistor (FET) or a bipolar junction transistor (BJT). The active component may also be a high electron mobility transistor (HEMT) or a gallium nitride high electron mobility transistor (GaN HEMT).

As disclosed in the above description and attached drawings, the present invention can provide an advanced moisture resistant structure of compound semiconductor integrated circuit. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

1-6. (canceled)

7. An advanced moisture resistant structure of compound semiconductor integrated circuit comprises:
a compound semiconductor substrate;
a compound semiconductor epitaxial structure formed on said compound semiconductor substrate;
a compound semiconductor integrated circuit formed on said compound semiconductor epitaxial structure; and
a moisture barrier layer formed on said compound semiconductor integrated circuit, wherein said moisture barrier layer includes a first moisture barrier layer and a second moisture barrier layer, said first moisture barrier layer is made of Al₂O₃, a thickness of said first moisture barrier layer is greater than or equal to 100 Å and less than or equal to 1000 Å,
wherein said second moisture barrier layer is made of silicon nitride (SiNₓ), and
wherein a thickness of said second moisture barrier layer is greater than or equal to 3000 Å and less than or equal to 10000 Å so as to enhance the moisture resistant ability of said compound semiconductor integrated circuit.

8. The advanced moisture resistant structure of compound semiconductor integrated circuit according to claim 7, wherein said second moisture barrier layer is formed on said compound semiconductor integrated circuit, said first moisture barrier layer is formed on said second moisture barrier layer.

9. (canceled)

10. (canceled)

11. The advanced moisture resistant structure of compound semiconductor integrated circuit according to claim 7, wherein said first moisture barrier layer is formed on said compound semiconductor integrated circuit, said second moisture barrier layer is formed on said first moisture barrier layer.

12. (canceled)

13. The advanced moisture resistant structure of compound semiconductor integrated circuit according to claim 7, wherein said compound semiconductor integrated circuit includes at least one of an active component and a passive component.

14. The advanced moisture resistant structure of compound semiconductor integrated circuit according to claim 13, wherein said active component includes at least one selected from the group consisting of a heterojunction bipolar transistor, a high electron mobility transistor, a pseudomorphic high electron mobility transistor, a gallium nitride high electron mobility transistor, a bipolar junction transistor and a field effect transistor.

15. The advanced moisture resistant structure of compound semiconductor integrated circuit according to claim 7, wherein said compound semiconductor integrated circuit includes at least one electrical wire.

16. The advanced moisture resistant structure of compound semiconductor integrated circuit according to claim 7, wherein said compound semiconductor substrate is made of one material selected from the group consisting of quartz, GaAs, sapphire, InP, GaP, SiC, diamond and GaN.

17. The advanced moisture resistant structure of compound semiconductor integrated circuit according to claim 7, wherein said moisture barrier layer covers an external surface of said compound semiconductor integrated circuit.

18. (canceled)

19. An advanced moisture resistant structure of compound semiconductor integrated circuit comprises:
a compound semiconductor substrate;
a compound semiconductor epitaxial structure formed on said compound semiconductor substrate;
a compound semiconductor integrated circuit formed on said compound semiconductor epitaxial structure; and
a moisture barrier layer formed on said compound semiconductor integrated circuit,
wherein said moisture barrier layer includes a first moisture barrier layer and a second moisture barrier layer, said first moisture barrier layer is made of Al₂O₃, a thickness of said first moisture barrier layer is greater than or equal to 100 Å and less than or equal to 1000 Å,
wherein said second moisture barrier layer is made of one material selected from the group consisting of Polybenzoxazole (PBO), Benzocyclobutene (BCB) and Polyimide, and
wherein a thickness of said second moisture barrier layer is greater than or equal to 1 μm and less than or equal to 5 μm, so as to enhance the moisture resistant ability of said compound semiconductor integrated circuit.

20. The advanced moisture resistant structure of compound semiconductor integrated circuit according to claim 19, wherein said second moisture barrier layer is formed on said compound semiconductor integrated circuit, said first moisture barrier layer is formed on said second moisture barrier layer.

21. The advanced moisture resistant structure of compound semiconductor integrated circuit according to claim 19, wherein said first moisture barrier layer is formed on said compound semiconductor integrated circuit, said second moisture barrier layer is formed on said first moisture barrier layer.

22. The advanced moisture resistant structure of compound semiconductor integrated circuit according to claim 19, wherein said compound semiconductor integrated circuit includes at least one of an active component and a passive component.

23. The advanced moisture resistant structure of compound semiconductor integrated circuit according to claim 22, wherein said active component includes at least one selected from the group consisting of a heterojunction bipolar transistor, a high electron mobility transistor, a pseudomorphic high electron mobility transistor, a gallium nitride high electron mobility transistor, a bipolar junction transistor and a field effect transistor.

24. The advanced moisture resistant structure of compound semiconductor integrated circuit according to claim 19, wherein said compound semiconductor integrated circuit includes at least one electrical wire.

25. The advanced moisture resistant structure of compound semiconductor integrated circuit according to claim 19, wherein said compound semiconductor substrate is made of one material selected from the group consisting of quartz, GaAs, sapphire, InP, GaP, SiC, diamond and GaN.

26. The advanced moisture resistant structure of compound semiconductor integrated circuit according to claim 19, wherein said moisture barrier layer covers an external surface of said compound semiconductor integrated circuit.
